(19) United States
(12) Patent Application Publication
(10) Pub. No.: US 2009/0038837 A1
(43) Pub. Date: Feb. 12, 2009

(54) Multilayered printed circuit board and manufacturing method thereof

(75) Inventors: Shuhichi Okabe, Suwon (KR); Jin-Yong An, Seo-gu (KR); Seok-Kyu Lee, Suwon-si (KR); Soon-Oh Jung, Suwon-si (KR); Jong-Kuk Hong, Suwon-si (KR); Hae-Nam Seo, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/078,176

(22) Filed: Mar. 27, 2008

(30) Foreign Application Priority Data
Aug. 10, 2007 (KR) 10-2007-0080945

(51) Int. Cl. H05K 1/11; B32B 38/10

(52) U.S. Cl. 174/262; 156/151

(57) ABSTRACT

A multilayered printed circuit board is disclosed. A method of manufacturing the multilayered printed circuit board, which includes: forming a metal layer and a lower-circuit-forming pattern in order on a carrier, and forming a lower circuit by filling a conductive material in the lower-circuit-forming pattern; removing the lower-circuit-forming pattern, stacking an insulation resin, and forming at least one via hole connecting with the lower circuit; forming at least one inner circuit and at least one interlayer connector connecting the inner circuit with the lower circuit on the insulation resin, to form a pair of circuit parts; and aligning the pair of circuit parts, attaching the pair of circuit parts to each other, and removing the carrier and the metal layer, allows the forming of fine-lined circuits and provides a thin board, while preventing bending and warpage in the board.

### CROSS-REFERENCE TO RELATED APPLICATIONS

This application claims the benefit of Korean Patent Application No. 10-2007-0080945 filed with the Korean Intellectual Property Office on Aug. 10, 2007, the disclosure of which is incorporated herein by reference in its entirety.

### BACKGROUND

1. Technical Field

The present invention relates to a multilayered printed circuit board and to a method of manufacturing the multilayered printed circuit board.

2. Description of the Related Art

In step with the trends in electronic devices towards higher performances and smaller sizes, the need is growing for enhancing the functions of circuit components and increasing package density. There is also a need for improving the module to which the circuit components are joined, for increasing package density and functionality. The current trend is to mount the circuit components on a circuit board having a multilayer structure, so that the package density may be improved. In particular, the multilayer printed circuit board that uses connection by inner vias is commonly utilized as a means for increasing circuit density. Furthermore, the component-integrated circuit board is being developed, in which wiring patterns connect the mounting area with the LSI areas or the components by as short a distance as possible to reduce space.

With the printed circuit board continuously becoming lighter, thinner, and simpler, the width and pitch of the circuit patterns are reaching extremely low values. In these printed circuit boards having low thicknesses and fine-line circuits, the circuit patterns are prone to delamination, causing a higher defect rate, while the board itself is subject to problems such as bending and warpage, etc.

### SUMMARY

An aspect of the invention is to provide a multilayered printed circuit board having a low thickness and a method of manufacturing the multilayered printed circuit board.

Another aspect of the invention is to provide a multilayered printed circuit board and a manufacturing method thereof, in which the board is protected from bending and warpage. Yet another aspect of the invention is to provide a multilayered printed circuit board and a manufacturing method thereof, in which fine-line circuits can be formed on the outermost layers.

One aspect of the invention provides a multilayered printed circuit board that includes: a pair of circuit parts, which each has a lower circuit and at least one inner circuit formed over the lower circuit that are electrically connected by at least one interlayer connector, where the pair of circuit parts are arranged and stacked together such that the lower circuit positioned on each of the circuit parts faces outwards.

Embodiments of the multilayered printed circuit board may include one or more of the following features. For example, the interlayer connector can have a frustoconical shape, with the diameter of the interlayer connector increasing in a direction from the lower circuit towards the inner circuit, and the diameter of the interlayer connector can decreasing in a direction from a center of the multilayered printed circuit board towards the exterior. In the pair of circuit parts, the inner circuits may be stacked in equal numbers. Both of the outward sides of the multilayered printed circuit board can be formed substantially flat.

Another aspect of the invention provides a method of manufacturing a multilayered printed circuit board. The method includes: forming a metal layer and a lower-circuit-forming pattern in order on a carrier, and forming a lower circuit by filling a conductive material in the lower-circuit-forming pattern; removing the lower-circuit-forming pattern, stacking an insulation resin, and forming at least one via hole connecting with the lower circuit; forming at least one inner circuit and at least one interlayer connector connecting the inner circuit with the lower circuit on the insulation resin, to form a pair of circuit parts; and aligning the pair of circuit parts, attaching the pair of circuit parts to each other, and removing the carrier and the metal layer.

Embodiments of the method of manufacturing a multilayered printed circuit board may include one or more of the following features. For example, the carrier may be formed from metal, which can be a metal having a low coefficient of thermal expansion, such as Invar, copper, and nickel. The lower-circuit-forming pattern can be formed by a photoresist.

The lower-circuit-forming pattern can also be formed by semi-additive plating, and the metal layer can be formed by nickel plating. The metal layer can be formed by securing a copper foil onto the carrier. Specifically, in certain cases, the copper foil can be secured to the carrier by way of an adhesive, or by deposition.

The insulation resin may include glass cloth, and the via hole can be formed by laser. Also, the inner circuit can be formed by forming an inner-circuit-forming pattern on the insulation resin and performing semi-additive plating. The pair of circuit parts may have an equal number of layers.

A connection pattern including at least one connection hole can be formed on one of the circuit parts, and an inner layer connection plating can be formed in the connection hole.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing a multilayered printed circuit board according to an embodiment of the invention.

FIG. 2 is a cross-sectional view of a metal layer and a circuit-forming pattern formed on a carrier, in the method of manufacturing a multilayered printed circuit board according to an embodiment of the invention.

FIG. 3 is a cross-sectional view after forming a lower circuit, in the method of manufacturing a multilayered printed circuit board according to an embodiment of the invention.

FIG. 4 is a cross-sectional view after removing the circuit-forming pattern, in the method of manufacturing a multilayered printed circuit board according to an embodiment of the invention.

FIG. 5 is a cross-sectional view after stacking an insulation resin over the lower circuit, in the method of manufacturing a multilayered printed circuit board according to an embodiment of the invention.

FIG. 6 is a cross-sectional view after forming via holes in the insulation resin, in the method of manufacturing a multilayered printed circuit board according to an embodiment of the invention.

FIG. 7 is a cross-sectional view after forming an inner-circuit-forming pattern on the insulation resin, in the method of manufacturing a multilayered printed circuit board according to an embodiment of the invention.

FIG. 8 is a cross-sectional view after forming an inner circuit by performing plating in the inner-circuit-forming pattern, in the method of manufacturing a multilayered printed circuit board according to an embodiment of the invention.

FIG. 9 is a cross-sectional view after forming a connection pattern over the inner circuit, in the method of manufacturing a multilayered printed circuit board according to an embodiment of the invention.

FIG. 10 is a cross-sectional view after forming an inner layer connection plating by performing plating in the connection pattern, in the method of manufacturing a multilayered printed circuit board according to an embodiment of the invention.

FIG. 11 is a cross-sectional view after removing the connection pattern, in the method of manufacturing a multilayered printed circuit board according to an embodiment of the invention.

FIG. 12 and FIG. 13 are cross-sectional views after attaching the circuit parts and removing the carriers and metal layers, in the method of manufacturing a multilayered printed circuit board according to an embodiment of the invention.

### DETAILED DESCRIPTION

As the invention allows for various changes and numerous embodiments, certain embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

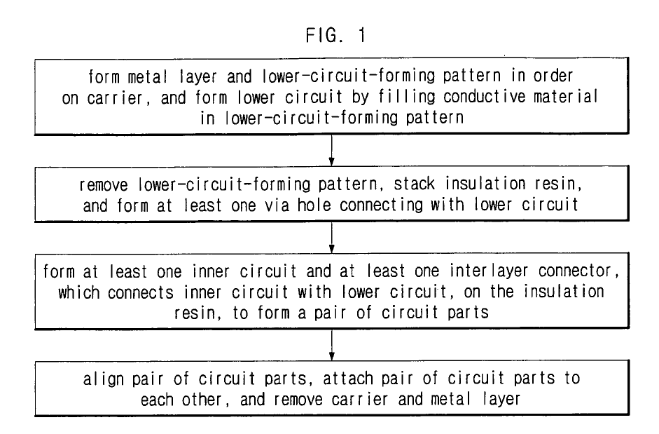

FIG. 1 is a flowchart illustrating a method of manufacturing a multilayered printed circuit board according to an embodiment of the invention.

Referring to FIG. 1, the manufacturing method for a multilayered printed circuit board according to an embodiment of the invention may include forming a metal layer and a lower-circuit-forming pattern in order on a carrier, and forming a lower circuit by filling a conductive material in the lower-circuit-forming pattern; removing the lower-circuit-forming pattern, stacking an insulation resin, and forming at least one via hole connecting with the lower circuit; forming at least one inner circuit and at least one interlayer connector connecting the inner circuit with the lower circuit on the insulation resin, to form a pair of circuit parts; and aligning the pair of circuit parts, attaching the pair of circuit parts to each other, and removing the carrier and the metal layer.

With this manufacturing method for a multilayered printed circuit board according to an embodiment of the invention, the lower circuits, which become the outermost circuits, may be buried in the insulation resin, so that fine-line circuits may be formed. Also, in the manufacturing method for a multilayered printed circuit board according to an embodiment of the invention, a pair of circuit parts can be attached to each other, thereby preventing bending and warpage over the entire board.

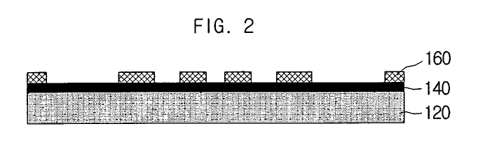

The method of manufacturing a multilayered printed circuit board according to an embodiment of the invention will be described below in greater detail, with reference to FIG. 2 through FIG. 13.

FIG. 2 is a cross-sectional view of a metal layer 140 and a lower-circuit-forming pattern 160 formed on a carrier 120, in the method of manufacturing a multilayered printed circuit board according to an embodiment of the invention.

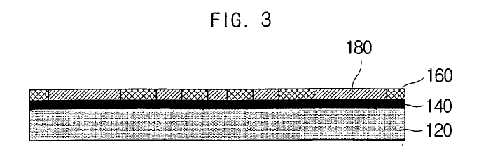

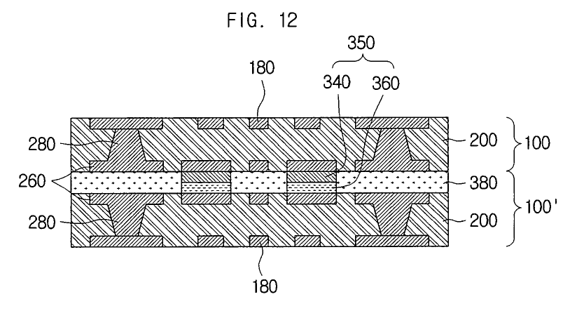

On the carrier 120, the metal layer 140 the lower-circuit-forming pattern 160 may be stacked in order, after which a lower circuit 180 (see FIG. 3) having at least one layer is formed. The carrier 120 can be formed from metal. In particular cases, a metal having a low coefficient of thermal expansion (CTE) can be used, to prevent bending, etc., that can occur due to the thermal expanding of the metal during a subsequent hot pressing operation applied to the circuit parts. Examples of metals having low coefficients of thermal expansion include Invar, nickel, and copper, etc. The carrier 120 may be removed after a pair of circuit parts are attached together (see FIG. 12).

The metal layer 140 formed on the carrier 120 may be formed by metal plating. If the metal layer 140 is formed by metal plating, copper or nickel plating may be utilized. A thin metal foil, such as a copper foil, can be secured to the carrier 120 using an adhesive, or the metal foil can be deposited onto the carrier 120 for securing. The metal layer 140 may serve to protect the carrier 120, when plating material is filled in the gaps in the lower-circuit-forming pattern 160 by plating, etc.

The lower-circuit-forming pattern 160 can be formed by applying a photoresist over the metal layer 140 and performing exposure and development. The lower-circuit-forming pattern 160 can correspond to the portions other than the lower circuit 180 (see FIG. 3) that is to be formed later, and a conductive material such as copper can be filled in the gaps in the lower-circuit-forming pattern 160 by plating.

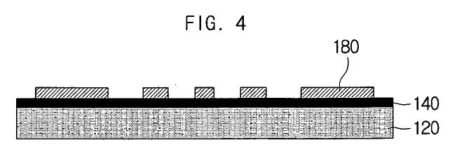

FIG. 3 is a cross-sectional view after forming the lower circuit 180 by performing metal plating in the gaps in the lower-circuit-forming pattern 160 of FIG. 2, and FIG. 4 is a cross-sectional view after removing the circuit-forming pattern 160 in FIG. 3.

Referring to FIG. 3, the lower circuit 180 can be formed in the gaps in the lower-circuit-forming pattern 160 by semi-additive plating procedures. When the carrier 120 is removed in a subsequent process, portions of the lower circuit 180 may be exposed to the exterior to become circuits on an outermost layer.

After the lower circuit 180 is formed, the lower-circuit-forming pattern 160 can be removed, so that only the lower circuit 180 may remain on the metal layer 140. The method of removing the lower-circuit-forming pattern 160 can be based on general procedures used in manufacturing a printed circuit board, and thus will not be set forth in further detail.

As such, in this embodiment, the lower circuit 180 may be formed using the lower-circuit-forming pattern 160, which makes it possible to form fine-lined lower circuits 180 on the outermost layers.

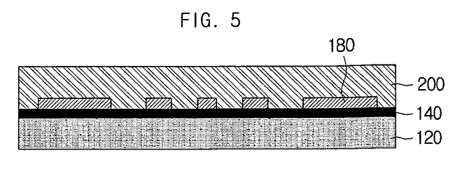

FIG. 5 is a cross-sectional view after stacking an insulation resin 200 on the lower circuit 180 in FIG. 4.

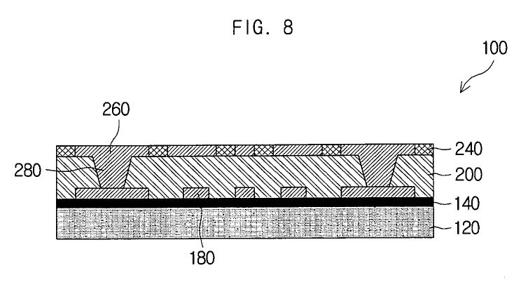

Referring to FIG. 5, an insulation resin 200 may be stacked and hot-pressed over the lower circuit 180, such that the insulation resin 200 may be filled in the gaps in the lower circuit 180. The insulation resin 200 may serve as insulation between the lower circuit 180 and the inner circuit 260 (see FIG. 8) formed later, and may serve as a protective coating that prevents the lower circuit 180 from peeling or warpage.

Glass cloth can be included in the insulation resin 200. The insulation resin 200 containing glass cloth can increase the rigidity of the overall board.

The insulation resin 200 can be formed from a thermosetting resin. Examples of thermosetting resins include phenol resins, melanin resins, urea resins, epoxy resins, phenoxy resins, epoxy modified polyimide resins, unsaturated polyester resins, polyimide resins, urethane resins, diallyl phthalate resins, etc. Such thermosetting resins can be used alone or in a mixed resin of two or more types.

A hardening agent can be used in the thermosetting resin, examples of which include polyphenol-based hardening agents, polyamine-based hardening agents, carboxylic acid hydrazide types, dicyan diamide, nylon salts and phosphates of imidazole type polyamine, Lewis acids and their amine chelates, etc. Such hardening agents can be used alone or in a mixture of two or more agents.

The insulation resin 200 can also be formed from a thermoplastic resin. Examples of thermoplastic resins include polyether sulfone, polysulfone, polyether imide, polystyrene, polyethylene, polyallylate, polyamide-imide, polyphenylene sulfide, polyether ketone, polyoxy benzoate, polyvinyl chloride, polyvinyl acetate, polyacetal, polycarbonate, etc. Such thermoplastic resins can be used alone, or two or more resins can be used together.

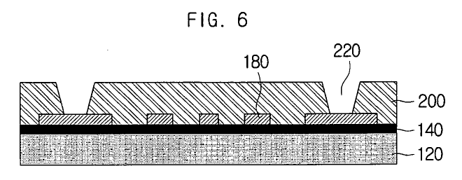

FIG. 6 is a cross-sectional view after forming via holes 220 in the insulation resin 200 of FIG. 5.

Referring to FIG. 6, the via holes 220 may penetrate the insulation resin 200 to connect with the lower circuit 180. Methods of forming the via holes 220 may generally include the use of a drill or laser, etc. In a subsequent process, the via holes 220 can be filled with a conductive material, such as copper, etc., whereby interlayer connectors 280 (see FIG. 8) may be formed which electrically connect the lower circuit 180 and the inner circuit 260.

As illustrated in FIG. 6, the via holes 220 may have a frustoconical shape, with the diameter decreasing towards the direction of the lower circuit 180. One reason why a via hole 220 has a frustoconical shape can be that, when using laser to form the via hole, the energy of the laser may decrease in proportion to the depth of the insulation layer 200.

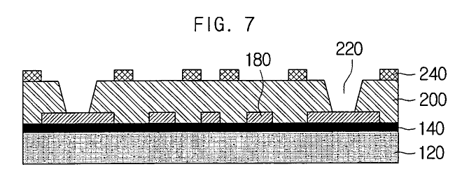

FIG. 7 is a cross-sectional view after forming an inner-circuit-forming pattern 240 on the insulation resin 200 in FIG. 6.

Referring to FIG. 7, an inner-circuit-forming pattern 240 may be formed over the insulation resin 200 by way of a photoresist. The inner-circuit-forming pattern 240 can be used in forming an inner circuit, and can be formed by substantially the same method as that for the lower-circuit-forming pattern 160. Through gaps in the inner-circuit-forming pattern 240, the via holes 220 may be exposed to the exterior.

FIG. 8 is a cross-sectional view after filling, by plating, the via holes 220 and the gaps in the inner-circuit-forming pattern 240 of FIG. 7.

Referring to FIG. 8, semi-additive plating procedures can be used to fill copper, etc., in the via holes 220 and the gaps in the inner-circuit-forming pattern 240. As a result, the inner circuit 260 and the interlayer connectors 280 may be formed, with the inner circuit 260 and lower circuit 180 electrically connected. As shown in FIG. 8, the lower circuit 180 and the inner circuit 260 may be electrically connected to form one circuit part 100. Such circuit parts 100 can be formed in symmetrical pairs and, after aligning, may be attached to each other to complete a multilayered printed circuit board.

As such, by using semi-additive plating to connect the inner circuit 260 to the lower circuit 180 at the same time the inner circuit 260 is formed, it is possible to obtain a circuit joined with high reliability. While this particular embodiment illustrates a circuit part 100 having a single layer of inner circuit, it is to be appreciated that the processes described above for forming the inner circuit 260 may be repeated as necessary to form two or more layers. Also, although the inner circuits can be formed by filling a conductive material in the gaps in the inner-circuit-forming patterns, the inner circuits may just as well be formed by a series of stacking copper foils on and etching, as used in general methods for forming circuits in a printed circuit board.

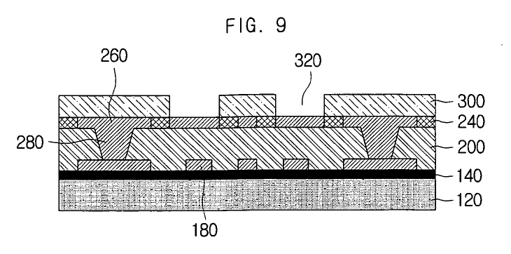

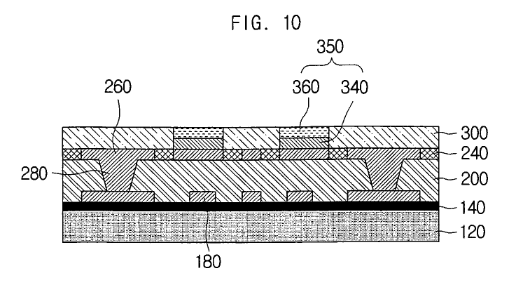

FIG. 9 is a cross-sectional view after forming a connection pattern 300, in order to form an inner layer connection plating for aligning the circuit parts 100, and FIG. 10 is a cross-sectional view after performing plating in the connection holes 320 of FIG. 9.

Referring to FIG. 9, a connection pattern 300 having connection holes 320 may be formed over the inner-circuit-forming pattern 240. The connection pattern 300 may also be formed by applying a photoresist and performing exposure and development. Then, as illustrated in FIG. 10, an inner layer connection plating 350, composed of a first connection plating 340 and a second connection plating 360, may be formed in the connection holes 320 by plating procedures. The first connection plating 340 can be of the same material as that of the inner circuit 260 (e.g. copper), while the second connection plating 360 can be made of a different metal from that used for the first connection plating 340.

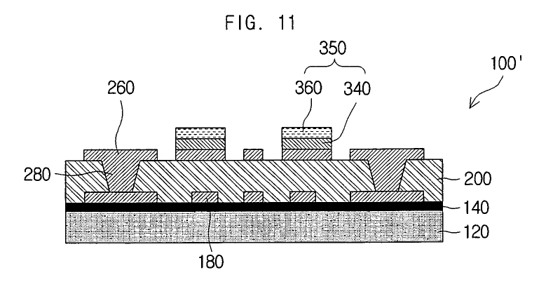

FIG. 11 is a cross-sectional view after removing the connection pattern 300 of FIG. 10.

Referring to FIG. 11, by removing the connection pattern 300, the first connection plating 340 and second connection plating 360 can be made to protrude upwards. The inner layer connection plating 350, composed of such upward-protruding first connection plating 340 and second connection plating 360, may serve not only to mark the positions for contact between circuit parts 100, but also to allow contact with the inner circuit of another pair of circuit parts.

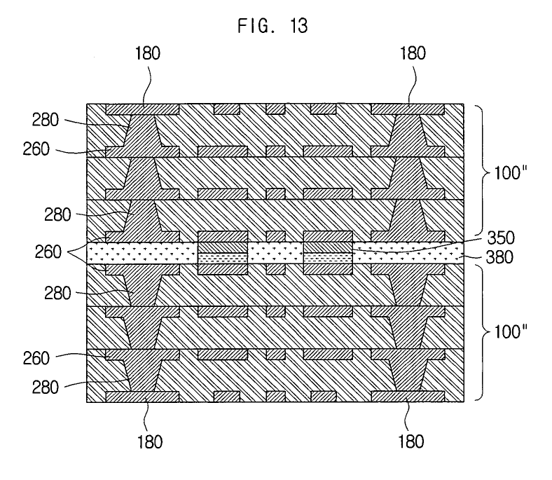

FIG. 12 and FIG. 13 are cross-sectional views after attaching the circuit parts 100, 100′ to each other.

In FIG. 12, there are illustrated a pair of circuit parts 100, 100′, including one circuit part 100 formed by the processes exampled in FIGS. 2 to 8 and one circuit part 100′ formed by the processes exampled in FIGS. 2 to 11. Each circuit part 100, 100′ can have the same number of layers, and FIG. 12 illustrates circuit parts 100, 100′ having one layer of inner circuit 260 respectively. Using the inner layer connection plating 350 as the reference points, the circuit parts 100, 100′ can be aligned using an LDI (Laser Direct Imaging) apparatus. An insulating adhesive 380 can be applied between the pair of circuit parts 100, 100′, which may be attached to each other by pressing the carriers 120 of the pair of circuit parts 100, 100′ together towards the insulating adhesive 380.

Where in this particular embodiment, the inner layer connection platings 350 may be formed as alignment marks for attaching the circuit parts 100, 100′ together, the position aligning can also be achieved using holes that may be formed in each of the carriers 120.

Referring to FIG. 12, in the procedure for attaching the circuit parts 100, 100′, the inner layer connection platings 350 formed on one circuit part 100′ can be in contact with the inner circuit 260 of the other circuit part 100. The insulating adhesive 380 may serve as insulation between the respective inner circuits 260 of the pair of circuit parts 100, 100′. Then, the carriers 120 on the top and bottom may be removed, and the metal layers 140 may be removed by etching, whereby the multilayered printed circuit board may be completed.

By thus attaching a pair of circuit parts 100, 100′ together, a multilayered printed circuit board having four layers may be completed. Of course, if circuit parts having three layers each are used, a multilayered printed circuit board having six layers can be obtained, and if circuit parts having four layers each are used, an eight-layer printed circuit board can be obtained.

Attaching in this manner the pair of circuit parts 100, 100′ that are substantially symmetrical to each other may not only prevent bending and warpage of the board but may also reduce the time for attaching the circuit parts 100, 100′. Also, since the pair of circuit parts 100, 100′ supported by metal carriers 120 undergo metal attachment only at the center portion, there is less metal attachment compared to the collective stacking method, so that there is a lower risk of incomplete attachment. Furthermore, in the case of a printed circuit board having ultra-high density circuits, a circuit of superb quality may be selected from either direction, so that the time and cost for manufacturing the multilayered printed circuit board may be reduced.

FIG. 13 is a cross-sectional view after attaching the pair of circuit parts and removing the carriers and metal layers, in the method of manufacturing a multilayered printed circuit board according to an embodiment of the invention.

Referring to FIG. 13, a pair of circuit parts 100″ having the same structure may be attached to each other to form a multilayered printed circuit board. In this particular example, each circuit part 100″ includes a lower circuit 180, formed as a single layer, and inner circuits 260, formed in three layers. Of course, the inner circuits 260 can be formed to have four or more layers. The connections between the lower circuit 180 and inner circuit 260, as well as the connections between inner circuits 260, can all be implemented by the interlayer connectors 280 formed in the via holes 220 (see FIG. 7). The interlayer connectors 280 can be frustoconical in shape, one reason for which can be that the via holes may be formed using laser, as described above. Therefore, the interlayer connectors 280 may be shaped to have the diameters increasing in directions from the lower circuit 180 towards the inner circuits 260.

The circuit parts 100″ may be disposed to have the lower circuits 180 facing the exterior and inner circuits 260 positioned inside the outermost lower circuits 180. Thus, the interlayer connectors 280 may be arranged such that the diameters decrease in directions from the center of the multilayered printed circuit board outward. As the pair of circuit parts 100″ having the same number of layers may be stacked in opposite directions, the structure of the multilayered printed circuit board can be symmetrical. An inner layer connection plating 350 may be formed on at least one circuit part 100″ to allow connection between the circuit parts 100″.

By thus attaching a pair of circuit parts 100″ that have substantially the same structure and an equal number of layers, bending and warpage, etc., can be prevented in the overall board during the stacking process.

On the inner circuit 260 corresponding to an outer layer on either side of the multilayered printed circuit board, a semiconductor component may be mounted, or an external connection terminal may be formed. As such, the outer layers on both sides of the multilayered printed circuit board can be formed without surface polishing as a flat structure.

According to certain embodiments of the invention as set forth above, a thin multilayered printed circuit board may be provided, as well as a method of manufacturing the thin multilayered printed circuit board.

Embodiments of the invention may also provide a multilayered printed circuit board and manufacturing method thereof, in which bending and warpage of the board can be prevented.

In addition, embodiments of the invention may also provide a multilayered printed circuit board and manufacturing method thereof, in which fine-lined circuits can be formed even on the outermost layers.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A multilayered printed circuit board comprising:
a pair of circuit parts each having at least one lower circuit and at least one inner circuit formed over the lower circuit, the lower circuit and the inner circuit electrically connected by at least one interlayer connector,
wherein the pair of circuit parts are arranged and stacked together such that the lower circuit positioned on each of the circuit parts faces outwards.

2. The multilayered printed circuit board of claim 1, wherein the interlayer connector has a frustoconical shape, a diameter of the interlayer connector increasing in a direction from the lower circuit towards the inner circuit,
and the diameter of the interlayer connector decreasing in a direction from a center of the multilayered printed circuit board towards the exterior.

3. The multilayered printed circuit board of claim 1, wherein the pair of circuit parts each have an equal number of the inner circuits stacked therein.

4. The multilayered printed circuit board of claim 1, wherein both outward sides of the multilayered printed circuit board are substantially flat.

5. A method of manufacturing a multilayered printed circuit board, the method comprising:
forming a metal layer and a lower-circuit-forming pattern in order on a carrier, and forming a lower circuit by filling a conductive material in the lower-circuit-forming pattern;
removing the lower-circuit-forming pattern, stacking an insulation resin, and forming at least one via hole connecting with the lower circuit;
forming a pair of circuit parts by forming at least one inner circuit and at least one interlayer connector connecting the inner circuit with the lower circuit on the insulation resin; and
aligning the pair of circuit parts, attaching the pair of circuit parts to each other, and removing the carrier and the metal layer.

6. The method of claim 5, wherein the carrier is formed from metal.

7. The method of claim 6, wherein the carrier is formed from a metal having a low coefficient of thermal expansion.

8. The method of claim 7, wherein the carrier is formed from any one selected from a group consisting of Invar, copper, and nickel.

9. The method of claim 5, wherein the lower-circuit-forming pattern is formed by a photoresist.

10. The method of claim 5, wherein the lower-circuit-forming pattern is formed by semi-additive plating.

11. The method of claim 5, wherein the metal layer is formed by nickel plating.

12. The method of claim 5, wherein the metal layer is formed by securing a copper foil on the carrier.

13. The method of claim 12, wherein the copper foil is secured to the carrier by way of an adhesive.

14. The method of claim 12, wherein the copper foil is secured to the carrier by deposition.

15. The method of claim 5, wherein the insulation resin includes glass cloth.

16. The method of claim 5, wherein the via hole is formed by laser.

17. The method of claim 5, wherein the inner circuit is formed by forming an inner-circuit-forming pattern on the insulation resin and performing semi-additive plating.

18. The method of claim 5, wherein the pair of circuit parts have an equal number of layers.

19. The method of claim 5, wherein a connection pattern including at least one connection hole is formed on one of the circuit parts, and an inner layer connection plating is formed in the connection hole.
